(19) United States
(12) Patent Application Publication
(10) Pub. No.: US 2021/0222295 A1
(43) Pub. Date: Jul. 22, 2021

(54) SYNTHESIS OF HEXAGONAL BORON NITRIDE FILMS AND TRANSFER METHOD

(71) Applicant: CAMBRIDGE ENTERPRISE LIMITED, Cambridge Cambridgeshire (GB)

(72) Inventors: Ruizhi WANG, Cambridge Cambridgeshire (GB); Stephan HOFMANN, Cambridge Cambridgeshire (GB)

(21) Appl. No.: 17/056,311

(22) PCT Filed: May 17, 2019
(86) PCT No.: PCT/GB2019/051378

§ 371 Date: Nov. 17, 2020

(30) Foreign Application Priority Data
May 18, 2018 (GB) 1808121.6

(51) Int. Cl. C23C 16/34; C01B 21/064; C23C 16/46; C23C 16/455; C23C 16/01

(52) U.S. Cl. CPC C23C 16/342; C01B 21/0646; C01P 2004/03; C23C 16/45557; C23C 16/01; C23C 16/46

(57) ABSTRACT

A method of producing hexagonal boron nitride by chemical vapour deposition on a substrate, the method comprising: (a) a step of heating the substrate at a first temperature for a first time; (b) a step of exposing the substrate to a precursor containing boron and a precursor containing nitrogen at a first partial pressure of the precursor(s) at a second temperature for a second time, wherein either a single precursor is used as the precursor containing boron and as the precursor containing nitrogen or different precursors are used as the precursor containing boron and the precursor containing nitrogen; (c) a step of heating the substrate at a third temperature for a third time without the precursor; and (d) a step of exposing the substrate to the precursors at a fourth temperature at a second partial pressure of the precursor(s) for a fourth time.

### FIELD AND BACKGROUND

The present disclosure relates to methods of synthesising high-quality hexagonal boron nitride. This is particularly useful for, but not limited to, the fabrication of heterostructures comprising a plurality of two-dimensional materials (2DMs)

In recent years there has been interest in the potential of 2DMs due to their impressive range of unique intrinsic properties following the isolation of graphene by Andre Geim and Konstantin Novoselov at the University of Manchester in 2004 for which they were awarded the Physics Nobel Prize in 2010.

Following the isolation of graphene many other 2DMs have been isolated. Of particular interest is hexagonal Boron Nitride (h-BN) which has similar lattice parameters and inter-layer spacing to graphene but unlike graphene, which is a zero-gap semiconductor, h-BN is an insulator. This makes h-BN an ideal substrate for graphene which normally exhibits greatly diminished properties on typical substrates due to undulations in the surface of the substrate and graphene-substrate interactions. As such there has been interest in fabricating “heterostructure” devices comprising a plurality of layers of graphene and h-BN.

To date only small area graphene-h-BN heterostructure devices have been fabricated due to difficulties in producing large wafer-scale areas of graphene and h-BN which can be transferred from a growth to device substrate.

Originally both graphene and h-BN were fabricated using physical exfoliation which, while producing high-quality material, is typically limited in scale to a few 10s of micrometres. Other large-scale fabrication techniques have been developed, principally Chemical Vapour Deposition (CVD), which are capable of fabricating graphene and h-BN at the wafer-scale (tens of centimetres).

While CVD has been shown to be capable of fabricating both wafer-scale graphene and h-BN it has proved difficult to transfer the graphene and h-BN to a device substrate without a significant deterioration in the materials' intrinsic properties. Recent attempts have been made to tackle the difficulties in transferring CVD-grown graphene but to-date, no practical approach to growing and transferring CVD-grown h-BN has been demonstrated while maintaining the intrinsic properties at a high-level.

At least certain embodiments of the present disclosure address one of more of these problems as set out above.

### SUMMARY

Particular aspects and embodiments are set out in the appended claims.

Viewed from one perspective, there can be provided a method of producing hexagonal boron nitride by chemical vapour deposition on a substrate, the method comprising: (a) a step of heating the substrate at a first temperature for a first time; (b) a step of exposing the substrate to a precursor containing boron and a precursor containing nitrogen at a first partial pressure of the precursor(s) at a second temperature for a second time, wherein either a single precursor is used as the precursor containing boron and as the precursor containing nitrogen or different precursors are used as the precursor containing boron and the precursor containing nitrogen; (c) a step of heating the substrate at a third temperature for a third time without the precursor; and (d) a step of exposing the substrate to the precursors at a fourth temperature at a second partial pressure of the precursor(s) for a fourth time.

The present approach can be considered as being broken into four main steps: (a) an annealing step; (b) a recrystallization/seeding step; (c) a homogenization step; and (d) a domain expansion step. Step (a) assists in cleaning debris from the substrate, reducing surface impurities on the substrate and facilitating initial recrystallization of the substrate. Step (b) provides for the initial nucleation of a plurality of h-BN crystal domains. Step (b) may also promote further recrystallization of the substrate material thus leading to larger uniform domains in the substrate on which the h-BN can form. Step (c) acts to shrink the h-BN crystal domains formed during step (b) thereby reducing the number of extant crystal domains. Step (d) acts to expand the remaining crystal domains while minimising the formation of further nucleation sites.

Thereby, the split between the initial nucleation, in step (b), and the domain expansion, in step (d) allows for a small number of large-area h-BN crystal domains to be grown.

In some examples, the second partial pressure is lower than the first partial pressure. Thereby, conditions may be provided which promote nucleation in step (b) and suppress nucleation in step (d) while still allowing for domain expansion.

In some examples, the first partial pressure is between 1×10⁻⁶ mbar and 1×10⁻² mbar and the second partial pressure is between 1×10⁻⁷ mbar and 1×10⁻² mbar.

In further examples, the first partial pressure is between 5×10⁻⁶ mbar and 1.5×10⁻⁵ mbar and the second partial pressure is between 1×10⁻⁶ mbar and 4×10⁻⁶ mbar. In preferred examples, the first partial pressure is between 9×10⁻⁶ mbar and 1.1×10⁻⁵ mbar and the second partial pressure is between 2×10⁻⁶ mbar and 3×10⁻⁶ mbar.

In some examples, the first partial pressure may be any of, or any sub-range between, 5×10⁻⁶ mbar, 6×10⁻⁶ mbar, 7×10⁻⁶ mbar, 8×10⁻⁶ mbar, 9×10⁻⁶ mbar, 1.0×10⁻⁵ mbar, 1.1×10⁻⁵ mbar, 1.2×10⁻⁵ mbar, 1.3×10⁻⁵ mbar, 1.4×10⁻⁵ mbar and 1.5×10⁻⁵ mbar. In some examples, the second partial pressure may be any of, or any sub-range between, 1×10⁻⁶ mbar, 1.5×10⁻⁶ mbar, 2×10⁻⁶ mbar, 2.5×10⁻⁶ mbar, 3×10⁻⁶ mbar, 3.5×10⁻⁶ mbar and 4×10⁻⁶ mbar. Thereby, conditions may be provided which promote nucleation in step (b) and suppress nucleation in step (d) while still allowing for domain expansion.

In some examples, a single precursor is used as the precursor containing boron and the precursor containing nitrogen and wherein the precursor is one of borazine, ammonia borane and trichloroborazine. Thereby, a single precursor can be provided which acts both as the boron precursor and as the nitrogen precursor thus simplifying the delivery of precursor to the growth chamber as only a single gas needs to be delivered and a single associated pressure need be controlled.

In some examples, the precursor containing boron is one of triisopropyl borate, triphenylborane, boron trichloride, diborane and decaborane; and the precursor containing nitrogen is one of ammonia and nitrogen. Thereby, the quantity of available boron and nitrogen can be separately controlled thus allowing for further refinement of growth and recrystallization conditions.

In some examples, the substrate is platinum or a platinum alloy. Platinum acts as a good catalyst for growth of h-BN and has a weak adhesion to h-BN after growth. Accordingly, the use of platinum facilitates the transfer of h-BN to a device substrate after growth. The use of the term device substrate refers, for example, to any target substrate on which it is desired to deposit the h-BN after growth. Other examples of catalysts with weak adhesion which may be used as a catalyst to grow h-BN are germanium, copper, silver, gold, iridium and alloys which include one or more of these species. The use of a weak adhesion material as the substrate facilitates the re-use of the substrate as the h-BN can be removed from the substrate in a non-destructive manner, such as exfoliation, which allows for the re-use of the substrate. Accordingly, the high-cost of using platinum can be offset through re-use.

The use of platinum allows a broad range of parameter space to be accessed when selecting parameters during the CVD growth process as platinum is chemically inert up to high-temperatures and hence high-temperatures may be used. This chemical inertness further minimises the need for surface treatments such as oxide removal. Further, in step (b) the platinum substrate may undergo recrystallization which increases the size of the platinum crystal domains through, as best understood, the dissolution of boron from the boron precursor into the platinum substrate. The dissolved boron acts as a deoxidizer which removes impurities present at grain boundaries which inhibit grain growth. The increased size of platinum crystal domains in turn promotes the growth of large single crystal domains of h-BN. In other examples where the substrate is formed from other metals, either in pure or alloy forms, the deoxidizer effect of boron also acts to remove impurities present at grain boundaries which inhibit grain growth and hence also promotes the increase in the size of the substrate crystal domains.

In some examples, the substrate is platinum foil. Thereby, a platinum substrate can be easily prepared and is easy to use. In other examples deposited platinum thin films or bulk platinum may be used.

In some examples, the substrate is formed of monocrystalline platinum. Thereby, the domain size of the platinum substrate is increased thus promoting the growth of large single crystal domains of h-BN.

In some examples, the substrate is initially formed of polycrystalline platinum and step (b) causes recrystallization of the platinum substrate from polycrystalline to single crystal form. Thereby, the crystal domain size of the platinum substrate is increased thus promoting the growth of large single crystal domains of h-BN.

In some examples, the first temperature is between 900° C. and 1400° C. In further examples, the first temperature is between 1170° C. and 1250° C. In preferred examples, the first temperature is between 1180° C. and 1220° C. In some examples the first temperature may be any of, or any sub-range between, 1150° C., 1160° C., 1170° C., 1180° C., 1190° C., 1200° C., 1210° C., 1220° C., 1230° C., 1240° C., 1250° C., 1300° C. and 1350° C.

Thereby, the substrate is provided with sufficient heat to clean debris, reduce surface impurities on the substrate and facilitate initial recrystallization of the substrate without causing the substrate to melt.

In some examples, the second temperature is between 900° C. and 1400° C. In further examples, the second temperature is between 1170° C. and 1250° C. In preferred examples, the second temperature is between 1180° C. and 1220° C. In some examples the second temperature may be any of, or any sub-range between, 1150° C., 1160° C., 1170° C., 1180° C., 1190° C., 1200° C., 1210° C., 1220° C., 1230° C., 1240° C., 1250° C., 1300° C. and 1350° C.

Thereby, the rate of nucleation is kept to a low, non-zero rate. Furthermore, the temperature is sufficient to allow further recrystallization in suitable substrates such as platinum.

In some examples, the third temperature is between 900° C. and 1400° C. In further examples, the third temperature is between 1170° C. and 1250° C. In preferred examples, the third temperature is between 1180° C. and 1220° C. In some examples the third temperature may be any of, or any sub-range between, 1150° C., 1160° C., 1170° C., 1180° C., 1190° C., 1200° C., 1210° C., 1220° C., 1230° C., 1240° C., 1250° C., 1300° C. and 1350° C.

Thereby, the temperature is sufficiently high to allow for dissociation of at least a portion of the h-BN crystals formed in step (b) while being sufficiently low that not all such crystals dissociate.

In some examples, the fourth temperature is between 900° C. and 1400° C. In further examples, the fourth temperature is between 1170° C. and 1250° C. In preferred examples, the fourth temperature is between 1180° C. and 1220° C. In some examples the fourth temperature may be any of, or any sub-range between, 1150° C., 1160° C., 1170° C., 1180° C., 1190° C., 1200° C., 1210° C., 1220° C., 1230° C., 1240° C., 1250° C., 1300° C. and 1350° C.

Thereby, the temperature is sufficient to allow for domain expansion of extant h-BN crystal domains while suppressing the formation of further nucleation sites.

In some examples, the first, second, third and fourth temperatures are substantially the same. Thereby, the CVD growth chamber can be kept at a constant temperature thus simplifying control and reducing the energy associated with increasing and decreasing the temperature of the chamber.

In some examples, the first time is at least 5 minutes. In some examples, the first time may be equal to or greater than any of 10 seconds, 5 minutes, 10 minutes, 15 minutes, 20 minutes, 25 minutes and 30 minutes. In preferred examples, the first time is at least 10 minutes. Thereby, time is sufficient to allow for a cleaning of debris and a reduction in surface impurities on the substrate.

In some examples, the second time is between 1 minute and 10 minutes. In further examples, the second time is between 2 and 6 minutes. In preferred examples, the second time is between 3 and 4 minutes. In some examples the second time may be any of, or any sub-range between, 1 minute, 2 minutes, 3 minutes, 4 minutes, 5 minutes, 6 minutes, 7, minutes, 8 minutes, 9 minutes, 10 minutes or 30 minutes.

Thereby, the time is sufficiently long to allow for initial nucleation sites to form but not long enough for significant successive rounds of further nucleation sites to form. Thereby, the number of nucleation sites is minimised which assists in the formation of large domains of h-BN.

In some examples, the third time is between 1 minute and 30 minutes. In further examples, the third time is between 2 minutes and 10 minutes. In preferred examples, the third time is between 4 minutes and 6 minutes. In some examples, the third time may be any of, or any sub-range between, 1 minute, 2 minutes, 3 minutes, 4 minutes, 5 minutes, 6 minutes, 7, minutes, 8 minutes, 9 minutes, 10 minutes or 30 minutes.

Thereby, the time is sufficient to allow for partial dissociation of the h-BN crystal domains while still leaving a sufficient number of crystal domains to allow for adequate growth during h-BN during step (d). In this manner, it is understood that small domains will fully disassociate and that after step (d) there will be a relatively low number of large-area single crystal domains of h-BN.

In some examples, the fourth time is between 5 minutes and 60 minutes. In further examples, the fourth time is between 5 minutes and 20 minutes. In preferred examples, the fourth time is between 8 minutes and 12 minutes. In some examples, the fourth time may be any of, or any sub-range between, 5 minutes, 6 minutes, 7, minutes, 8 minutes, 9 minutes, 10 minutes, 11 minutes, 12 minutes, 13 minutes, 14 minutes, 15 minutes, 16 minutes, 17 minutes, 18 minutes, 19 minutes, 20 minutes, 30 minutes and 60 minutes.

Thereby, the time is sufficient to allow for domain expansion of extant h-BN crystal domains while suppressing the formation of further nucleation sites.

Viewed from one perspective, there can be provided a method of transfer of hexagonal boron nitride produced by any of the previously described approaches from a first substrate to a second substrate, the method comprising: (e) applying to the hexagonal boron nitride a carrier material, the carrier material having a higher adhesion to the hexagonal boron nitride than the adhesion of the hexagonal boron nitride to the first substrate, such that the hexagonal boron nitride adheres to the carrier material; (f) removal of the carrier material having the hexagonal boron nitride adhered thereto from the first substrate; (g) applying the carrier material having the hexagonal boron nitride adhered thereto to the second substrate; and (h) removal of the carrier material.

Thereby, the present approach provides for a method by which h-BN may be transferred from a growth substrate to a device substrate. This approach minimises damage to the growth substrate thus allowing the re-use of the growth substrate which is of particular importance with high-cost catalysts such as platinum. Furthermore, this approach minimises contamination of the grown h-BN, thus maintaining the desired high-quality intrinsic properties of the h-BN. From one perspective, the present approach can be considered as an exfoliation-based approach which uses a “stamp” made from carrier material. The term “stamp” can be thought of, for example, as referring to a body of material which assists in the handling of the material attached/adhered to the stamp. In some examples, the carrier material is drop cast onto the grown h-BN, subsequently the carrier material is peeled off together with the h-BN, the carrier material with the h-BN is then deposited on a new substrate and finally the carrier material is removed.

The present approach is in contrast with prior techniques which, for example, rely on dissolving the growth substrate (e.g. wet transfer). As identified by the present inventor, this contaminates the grown h-BN as well as necessitating the provision of a new growth substrate for subsequent growth runs. Other prior techniques such as electrochemical delamination, while avoiding the need to dissolve the growth substrate, still exhibit substantial contamination of both the growth substrate and the grown h-BN.

In some examples, the carrier material is one of LOR (lift-off resist), PMMA (polymethyl methacrylate), PPC (polypropylene carbonate), PVB (polyvinyl butyral), CAB (cellulose acetate butyrate), PVP (polyvinylpyrrolidone), PC (polycarbonate) or PVA (polyvinyl alcohol). Thereby, carrier materials are provided which may have a higher adhesion to h-BN than h-BN has to the growth substrate and which may not cause damage to either the growth substrate or h-BN.

In some examples, steps (e)-(h) are repeated a plurality of times to build up a plurality of layers of hexagonal boron nitride on the second substrate. Thereby, multilayer h-BN can be easily fabricated. In some examples, a precise number of layers of h-BN can easily be fabricated. In some examples, the carrier layer together with a layer of attached h-BN may collectively be used as a “stamp” to pick up further layers of h-BN since the adhesion of a layer of h-BN to a second layer of h-BN may be stronger than the adhesion of the second h-BN layer to its substrate.

Similarly, heterostructures comprising a plurality of mixed layers of h-BN and other two-dimensional materials including, but not limited to, graphene, graphene derivatives and transition metal dichalcogenides may be fabricated using the “stamp” of a carrier layer with a layer of h-BN adhered. Such heterostructures may be fabricated as the adhesion of a layer of h-BN to a layer of two-dimensional material may be stronger than the adhesion of the two-dimensional material layer to the two-dimensional material layer's growth substrate.

General structures, where the h-BN is used as a capping layer can be fabricated using the “stamp” of a carrier layer with a layer of h-BN adhered. This includes the transfer of metal, semiconductor and insulating layers of any material, as long as the adhesion of these layers to h-BN is greater than the adhesion of these layers to their respective substrate.

In some examples, the second substrate is one of silicon, silicon dioxide, aluminium oxide, sapphire, germanium, gallium arsenide (GaAs), an alloy of silicon and germanium, and indium phosphide. Thereby, the h-BN can be transferred to a substrate which is suitable for device fabrication. It is to be understood that the list of substrate materials listed above represent examples of specific substrates but that the transfer technique described is understood to work with substantially any substrate.

Viewed from one perspective, there can be provided a chemical vapour deposition reactor configured to produce hexagonal boron nitride using the method of any of the previously described approaches. Thereby, a chemical vapour deposition reactor can be provided which can produce hexagonal boron nitride attaining one of more of the above described effects and advantages.

Viewed from one perspective, there can be provided a controller configured to control a chemical vapour deposition reactor to produce hexagonal boron nitride using the method of any of the previously described approaches. Thereby, a controller can be provided which enables a chemical vapour deposition reactor to produce hexagonal boron nitride attaining one of more of the above described effects and advantages.

Other aspects will also become apparent upon review of the present disclosure, in particular upon review of the Brief Description of the Drawings, Detailed Description and Claims sections.

### BRIEF DESCRIPTION OF THE DRAWINGS

Examples of the disclosure will now be described, by way of example only, with reference to the accompanying drawings in which:

FIG. 1: A illustrates a schematic overview of the novel Sequential Seeded Growth (SSG) h-BN growth process. B depicts representative Scanning Electron Microscope (SEM) images of the substrate at various stages of the growth process.

FIG. 2: A schematically illustrates the mechanisms associated with nucleation and domain expansion during the growth of h-BN crystals. B schematically illustrates the mechanisms associated with homogenization during the growth of h-BN crystals. C schematically illustrates the flux balance of active species in the substrate. D schematically illustrates the concentration of active species relative to the depth from the surface of the substrate at different example points in the growth process.

FIG. 3: Illustrates the effect of gas type on the recrystallization of the substrate during the recrystallization/seeding step.

FIG. 4: Illustrates the effect of temperature on the nucleation rate of h-BN.

FIG. 5: Illustrates the effect of precursor exposure duration on the nucleation density during the recrystallization/seeding step.

FIG. 6: Illustrates the effect of duration on the degree of dissociation during the homogenization step.

FIG. 7: Illustrates the degree of further nucleation with precursor exposure duration during the domain expansion step.

FIG. 8: A illustrates the weak adhesion of the h-BN to the substrate. B illustrates the process flow diagram of the exfoliation based transfer for producing layer stacks (heterostructures). C shows optical images of layer stacks produced using the transfer method.

FIG. 9: Illustrates results from an example device fabricated using the disclosed techniques.

FIG. 10: Illustrates a CVD chamber of the type which may be used to grow h-BN.

While the disclosure is susceptible to various modifications and alternative forms, specific example approaches are shown by way of example in the drawings and are herein described in detail. It should be understood however that the drawings and detailed description attached hereto are not intended to limit the disclosure to the particular form disclosed but rather the disclosure is to cover all modifications, equivalents and alternatives falling within the spirit and scope of the claimed invention.

It will be recognised that the features of the above-described examples of the disclosure can conveniently and interchangeably be used in any suitable combination.

### DETAILED DESCRIPTION

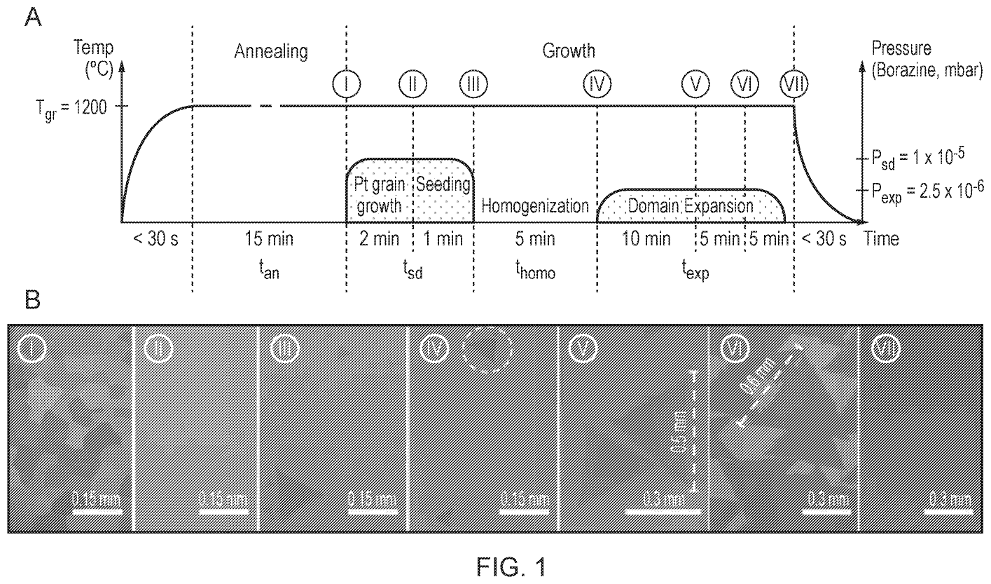

FIG. 1A shows a schematic overview of the novel h-BN CVD growth process discovered by the present inventor known as Sequential Seeded Growth (SSG). As in conventional approaches, the process is divided into an annealing stage and a growth stage. However, unlike conventional approaches the growth stage is itself split into three distinct steps. Specifically, the novel process is divided into four main steps (a) an annealing step; (b) recrystallization/seeding step; (c) a homogenization step; and (d) a domain expansion step.

FIG. 1A is schematically shows these four steps with a set of example parameters. FIG. 1B shows SEM images for this set of example parameters at example points in time within the process. The SEM images are taken from various locations across the substrate and are representative of the state at the example points in time. The example parameters depicted are merely representative of the particular set of conditions used to obtain the SEM images shown in FIG. 1B. Examples of other parameters are depicted in the later Figures together with the corresponding discussion in the detailed description. On the basis of numerical studies we estimate that further parameters will exhibit the inventive effects beyond those explicitly tested as discussed in greater detail below.

The annealing step, step (a), encompasses the time period up to point I. The annealing step serves to clean debris from the surface of the substrate, reduce surface defects and to cause some degree of recrystallization of the substrate. In the particular example, depicted in FIG. 1B, platinum foil is used as the growth substrate. The specific platinum foil used is from Alfa Aesar, is 25 μm thick and is of 99.99% purity. However, as can be seen in SEM image I, the platinum foil still contains a large number of individual domains after step (a); the domains having a typical domain size of approximately 0.1 mm. In the example, the temperature T_{gr} is raised to 1200° C. and then maintained for tₐₙ=15 minutes. From preliminary and numerical studies we estimate that any time longer than 5 minutes is sufficient to provide the outlined effects although it is explicitly contemplated that it may be possible to grow h-BN on substrates treated for shorter time periods.

The recrystallization/seeding step, step (b), encompasses the time period from point I to point III inclusive of point II. As can be seen from SEM image II significant further recrystallization is seen to occur during step (b) such that the platinum foil appears to be substantially monocrystalline. In the particular example, the temperature is kept constant and borazine is introduced into the CVD growth chamber at a pressure, P_{sd}, of 1×10⁻⁵ mbar for a time, t_{sd}, of 3 minutes. The addition of borazine is understood to be a key factor in promoting this significant further recrystallization. Specifically, the mechanism is understood to be caused by the catalytic decomposition of the borazine at the platinum substrate where a portion of the liberated boron is dissolved into the platinum. The dissolved boron acts as a deoxidiser. It removes impurities at the grain boundaries which inhibit platinum grain growth.

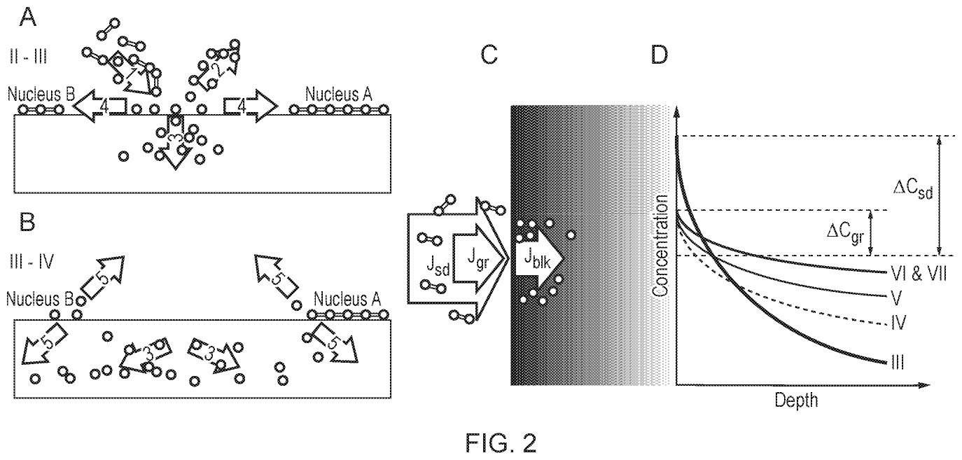

No significant further recrystallization is apparent between image II and image III. Image III does, however, show the initial nucleation of a small number of h-BN crystal domains. The mechanism by which these are formed is discussed in greater detail in relation to FIG. 2 below. A number of alternate parameter regimes for the seeding/recrystallization step are also explored in relation to Figures D, H and E below.

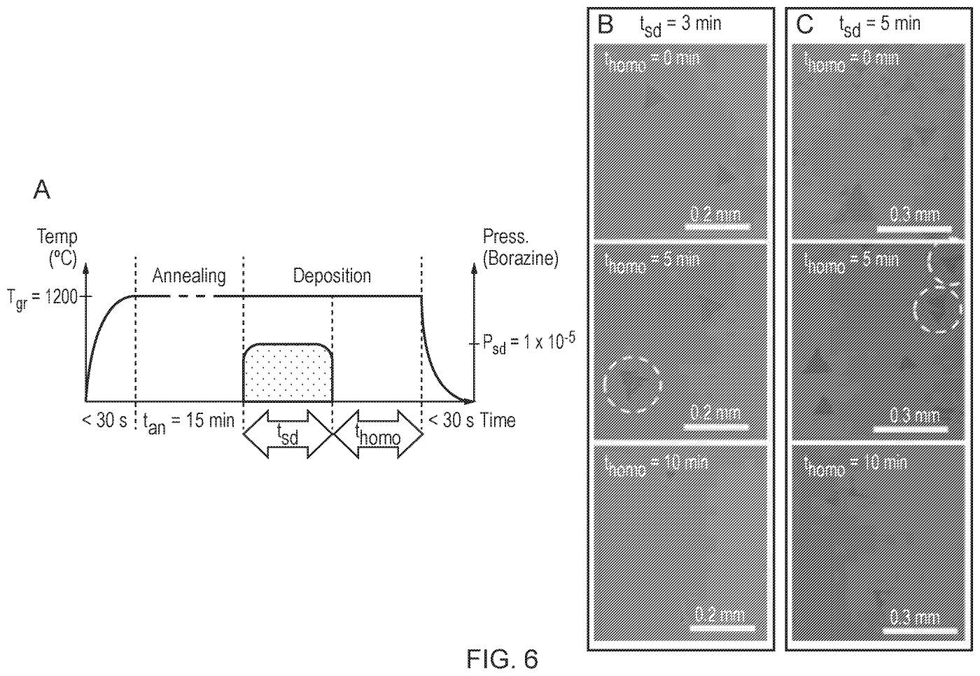

The homogenization step, step (c), encompasses the time period from point III to IV. In this step the borazine precursor is completely removed. In the depicted example, the temperature is again kept constant at 1200° C. As can be seen in image IV no further change is seen in the substrate itself but large h-BN crystal domains are seen to be in a state of partial dissociation, whereas small h-BN crystal domains have completely dissociated. This is most readily apparent inside the white dotted region on image IV where damage to the existing crystal domains is visible. This dissociation process acts to shrink the h-BN crystal domains formed during the recrystallization/seeding step such that only the larger crystal domains formed during the recrystallization/seeding step remain by point IV. In the depicted example the homogenization step is permitted to proceed for 5 minutes. The mechanism of dissociation will be discussed in greater detail in reference to FIG. 2 and its corresponding discussion below. Tuning of the duration of the homogenization step is discussed in relation to FIG. 6.

As discussed above, the novel SSG process identified by the present inventor separates the initial nucleation of crystal domains from the expansion of these domains. In SSG the domain expansion occurs primarily during the domain expansion step at step (d). The domain expansion step encompasses the time period from point IV to point VII inclusive of points V and VI. This domain expansion step is tuned to minimise further nucleation of h-BN crystal domains while providing conditions which allow for domain expansion. In the depicted example, the temperature is maintained at 1200° C. for a time period, tₑₓₚ, of 20 minutes. Notably, the pressure of the borazine precursor is significantly lower at 2.5×10⁻⁶ mbar than during the recrystallization/seeding step. This lower pressure helps to suppress further nucleation of h-BN crystal domains while still being sufficient to allow for expansion of the existing h-BN crystal domains.

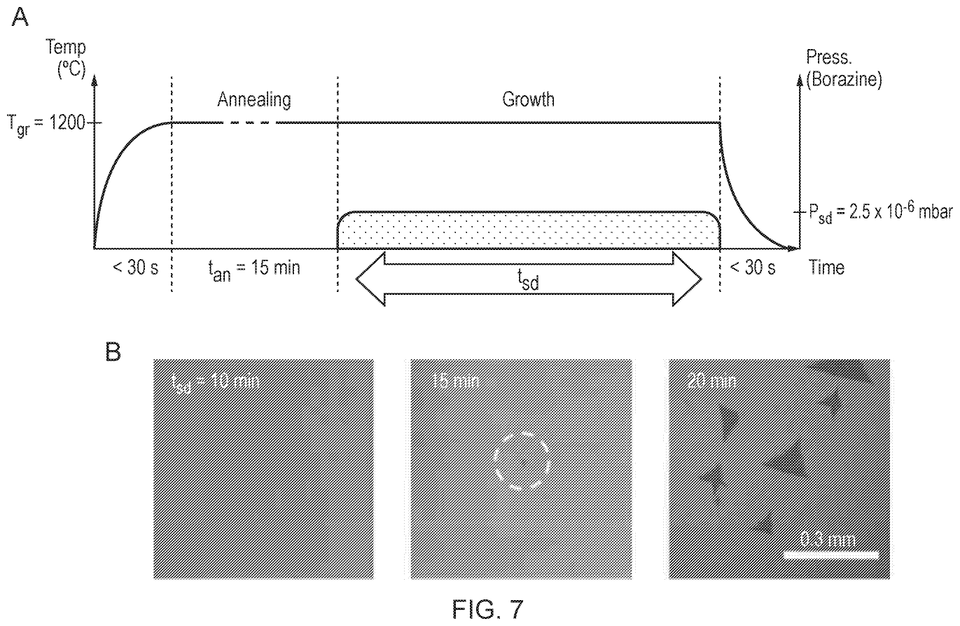

While in the depicted example further nucleation is suppressed relative to domain expansion through a reduction in the precursor pressure other parameter regimes to achieve this effect are also possible. Both the processes of nucleation and domain expansion are affected by all three of temperature, duration and pressure. Various alternate regimes are investigated and discussed in the further Figures and corresponding description. However, as can be seen in the differences in crystal domain size between images IV, V, VI and VII there is progressive growth in the size of domains. Specifically, the domain size at 15 minutes into the domain expansion step (image VI) is significantly larger than at 10 minutes (image V) into the step, which is in turn significantly larger than at the start of the step (image IV). As can further be seen, no further nucleation is apparent. This lack of further nucleation is further discussed below in relation to FIG. 7. Further, by image VII the h-BN domains have merged into a continuous film.

Turning now to FIG. 2, FIG. 2A and FIG. 2B schematically illustrate the mechanisms associated with nucleation, domain expansion and homogenization during the growth of h-BN crystal domains. FIG. 2C schematically illustrates the flux balance of active species in the substrate and FIG. 2D schematically illustrates the concentration of active species relative to the depth from the surface of the substrate at the different example points in the growth process shown in FIG. 1.

FIGS. 2A and 2B schematically illustrate the various processes taking place at the surface of the catalytic substrate. FIG. 2A shows the four primary transport processes occurring during the recrystallization/seeding step between point II and point III. Upon exposure to the precursor (1), the gas molecules absorb onto the catalyst substrate surface and are catalytically dissociated. These active species either desorb (2) or are absorbed into the bulk (3). Once the concentration at the catalyst surface has exceeded saturation, nucleation sets in (e.g. see nuclei A and B). The nuclei will grow through the active species diffusing across the surface and attaching themselves to the edges (4). As such, the concentration gradient in the substrate is decisive for the rate of nucleation and whether this rate is positive or negative. A similar set of processes will be present during the domain expansion step albeit with lower oversaturation such that further nucleation is suppressed.

FIG. 2B shows the transport processes during the homogenization step between point III and point IV. During this step, in the absence of additional precursor in combination with the high growth temperature, the existing nuclei are unstable and start to dissociate either desorbing or diffusing into the bulk (5).

The concentration gradient of the active species is dictated by the flux balance of the active species. As schematically shown in FIG. 2C during the recrystallization/seeding step, the incoming flux, J_{sd}, is significantly greater than the diffusive flux in the bulk, J_{blk} resulting in a large oversaturation at the substrate surface. In contrast, during the domain expansion step, the incoming flux is only marginally higher than the diffusive flux into the bulk, J_{blk}, thus resulting in a smaller oversaturation. This smaller saturation at the substrate surface is sufficient to allow for expansion of existing h-BN crystal domains but is insufficient to allow significant further nucleation.

For clarity, the same J_{blk} has been shown for both regimes, however, the value of J_{blk} is not necessarily the same for each regime. For example, higher temperatures will increase the diffusion rate and hence increase the diffusive flux away from the surface to the bulk of the substrate. As another example, the higher the existing concentration of active species in the bulk of the substrate, the greater the diffusion of the active species from the bulk back towards the surface and hence the lower the (net) flux from the substrate to the bulk. The existing concentration will depend, among other things, on the history of previous precursor pressures and exposure durations as well as the temperature of the growth chamber, the material of the catalytic substrate and the crystallinity of the catalytic substrate.

FIG. 2D schematically shows the concentrations of the active species relative to depth from the surface substrate for different example points in the growth process as indicated in FIG. 1. As can be seen, at point III, immediately following the recrystallization/seeding step, there is a high level of oversaturation, Δc_{sd}, which leads to increased nucleation. Accordingly, while the partial pressure of the precursor is maintained at these levels, the resulting precursor exposure not only results in the growth of existing nuclei but also in additional nucleation.

In contrast, during the domain expansion step at points IV, V, VI and VII, a far smaller oversaturation is exhibited, Δc_{gr}. This saturation does, however, build up with time such that, for steady applied precursor pressure and growth chamber temperature, the concentration profile becomes flatter and the probability of additional nucleation increases with time. This is shown in further detail in relation to FIG. 7, and its corresponding description, discussed below and acts to limit the effective maximum duration of the domain expansion step without significant further nucleation.

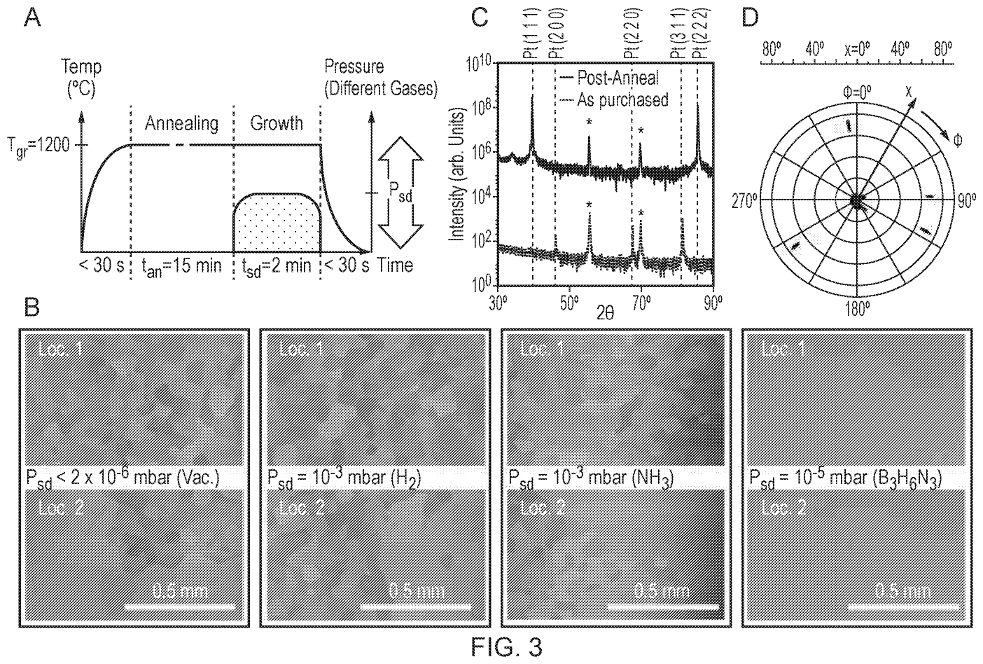

FIG. 3 illustrates the effect that gas type choice has on recrystallization of the substrate during the recrystallization/seeding step. FIG. 3A summarises the experimental conditions for this comparative test. Specifically, the temperature is heated to 1200° C. and held at this temperature for 15 minutes to perform an annealing step as per FIG. 1. Subsequently, either the vacuum is maintained, hydrogen is added at 10⁻³ mbar, ammonia is added at 10⁻³ mbar or borazine is added at 10⁻⁵ mbar to the growth chamber for 2 minutes as a “growth” step.

As can be seen from FIG. 3B, in the vacuum, hydrogen and ammonia conditions substantial polycrystallinity remains. It is only in the presence of a gas containing boron that further recrystallization beyond that caused by the annealing step is seen to occur. The difference in brightness between different orientations of crystal domains is due channelling contrast.

As stated above, this is understood to be because boron liberated by the catalytic decomposition of the borazine at the surface of the platinum substrate is dissolved into the platinum. The boron acts as a deoxidizer, which removes contaminants at the platinum grain boundaries responsible for grain pinning. On the basis of numerical simulations we understand that the borazine could be substituted for ammonia borane; trichloroborazine; or a combination either ammonia or nitrogen with triisopropyl borate, triphenylborane, boron trichloride, diborane or decaborane, as these chemicals are known to catalytically decompose in the presence of a platinum catalyst in a similar manner to borazine.

FIG. 3C shows an X-Ray Diffraction (XRD) spectrum of the platinum foil as purchased and after recrystallization in borazine using the conditions stated above. The spectra have been offset for improved visibility with the post-processed spectrum multiplied by 10⁴. All platinum peaks have been marked with their Miller index. The two peaks marked with a * originate from the tantalum susceptors on which the platinum foil was mounted on. As can be seen, after processing the (1 1 1) index dominates. It should be noted that the (2 2 2) index is equivalent to the (1 1 1). This demonstrates that significant recrystallization has in fact taken place. The (1 1 1) orientation of platinum is the most thermodynamically favourable state as it is the most densely packed and therefore requires the lowest activation energy. Accordingly, platinum is expected to preferentially crystalize in this orientation under most conditions.

This uniform recrystallization is of significant assistance in obtaining large area single crystal domains of h-BN as the orientation of the h-BN is itself affected by the domains in the platinum substrate. It is understood that there is a competition in the orientation of the h-BN crystal domains between either adapting to the underlying substrate lattice symmetry or minimizing the lattice mismatch with the substrate. In either case, there is a very high likelihood of defects in the h-BN occurring when h-BN crystal domains cross the boundaries of the platinum substrate domains due to a discontinuous change in preferential orientation that the h-BN crystal domains are trying to match. As such the recrystallization of platinum through dissolution of boron allows for larger h-BN crystal domains than would otherwise be possible.

FIG. 3D depicts a texture map of the Pt (1 1 1) reflection (at 28=39.732) which shows one pole in the symmetric position (χ∫˜0°) and 3 poles at χ^{˜}70° and ϕ=120° apart from each other. This demonstrates that the vast majority of the Pt grains have the same orientation, i.e. the grains are not rotated relative to each other, which is indicative for a pure single crystal.

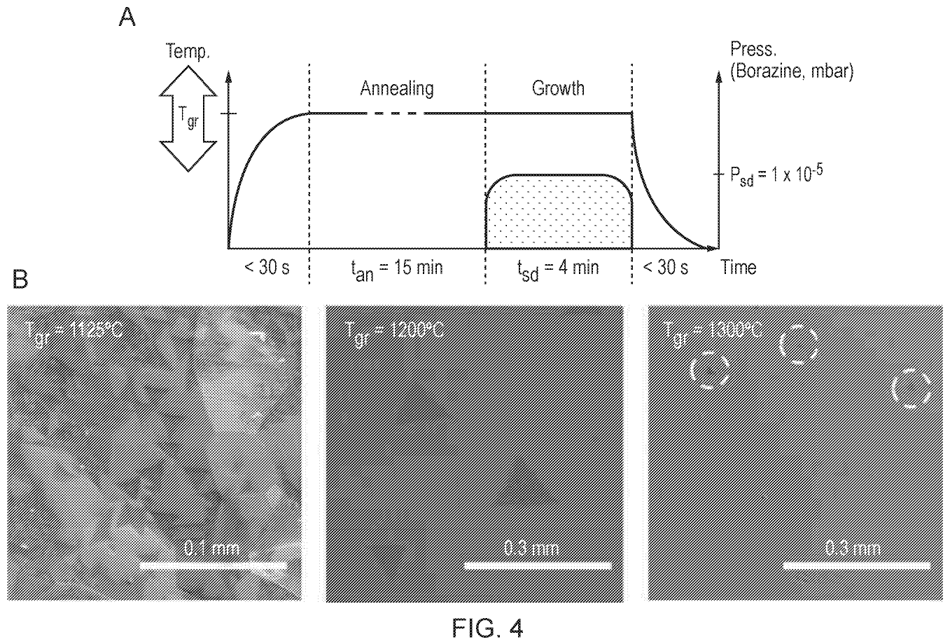

FIG. 4 illustrates the effect of temperature on the nucleation rate of h-BN crystal domains. FIG. 4A summarises the experimental conditions used for this comparative test. Again, initially the temperature is raised to a predetermined level and held at this temperature for 15 minutes to perform an annealing step. Subsequently, borazine is introduced at 1×10⁻⁵ mbar for 4 minutes at the same temperature as a growth step. In this comparative test, however, three different temperatures are tested, 1125° C., 1200° C. and 1300° C. Immediately, after the end of the growth step the sample is quenched and the substrate, with h-BN crystal domains, is imaged.

FIG. 4B shows the SEM images for each of the three tested temperatures. Note the scale on the 1125° C. image is zoomed in compared to the other two images for improved visibility. As can be seen, the nucleation rate decreases across the series with increasing temperature. This is in line with the theoretical reasoning given in relation to the discussion of FIG. 2 above as the basic growth model of CVD states that increased temperature results in longer surface and bulk diffusions radiuses.

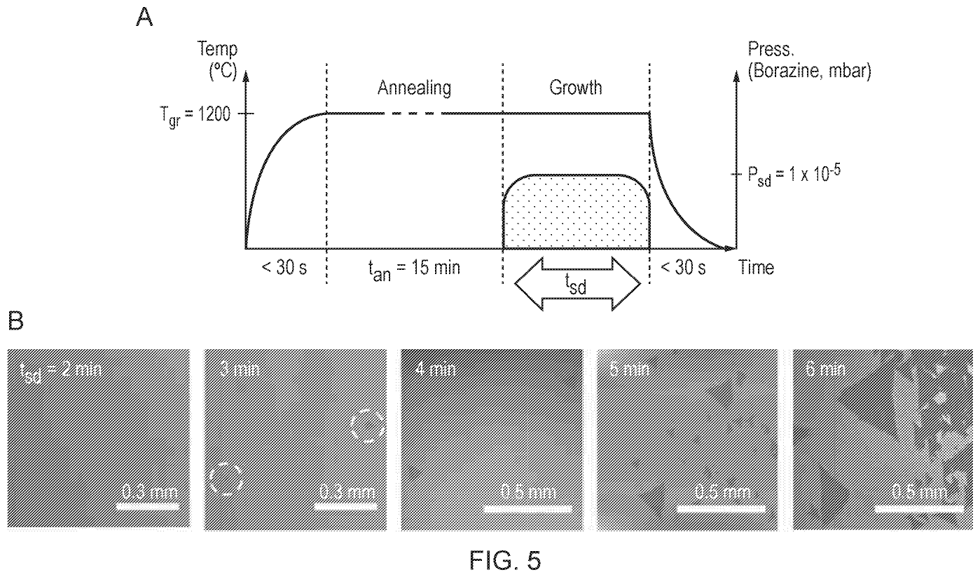

FIG. 5 illustrates the effect of growth time on the nucleation density during the recrystallization/seeding step. FIG. 5A summarises the experimental conditions for this comparative test. Specifically, the temperature is heated to 1200° C. and held at this temperature for 15 minutes. Subsequently, borazine is introduced at 1×10⁻⁵ mbar and is held at the same temperature for a variable number of minutes for the growth step. In the comparative test 2, 3, 4, 5 and 6 minutes are tested. After the growth step the samples were immediately quenched and imaged using SEM.

FIG. 5B shows SEM images for each tested duration. Note the scale on the 2 minutes and 3 minutes images are zoomed in compared to the other three images for improved visibility. As can be seen at 2 minutes, for the selected temperature and pressure, no nucleation is apparent. It is only at 3 minutes that onset of nucleation is apparent as marked by the white dotted circles. At times beyond 3 minutes the nuclei continue to grow, however, at 5 minutes the initial nuclei are joined by additional nuclei from further nucleation events. Accordingly, while very large “islands” may eventually be formed these will be formed from the coalescence of a plurality of smaller nuclei and hence the grown h-BN will be polycrystalline which is undesirable for high quality applications.

In addition to the effect of temperature on nucleation, as discussed in relation to FIG. 4 above, pressure of the precursor gas also has a tremendous effect on nucleation. This can be seen in the contrast between the comparative test shown in FIG. 5 (conducted at 1×10⁻⁵ mbar) with the comparative test shown in FIG. 7 (conducted at 2.5×10⁻⁶ mbar) which has only exhibits apparent nucleation at 15 minutes. FIG. 7 is discussed in further detail below.

FIG. 6 illustrates the effect of duration on the degree of dissociation during the homogenization step. FIG. 6A summarises the experimental conditions for this comparative test. This comparative test is again broken down into an annealing stage and growth stage. However, in this test the growth stage is broken down into a growth step followed by a homogenization step. The temperature is kept at a constant 1200° C. throughout. As before, the annealing step is 15 minutes. This is followed by a growth step with borazine introduced at 1×10⁻⁵ mbar for either 3 minutes or 5 minutes. This, time however, the growth step is followed by the novel homogenization step. In this step, the borazine precursor is removed. Three different durations for the homogenization step were tested followed by immediate quenching and imaging using SEM. Specifically, 0 minutes (i.e. no homogenization step), 5 minutes and 10 minutes were each tested.

FIG. 6B shows the corresponding SEM images for borazine introduced at 1×10⁻⁵ mbar for a time of 3 minutes for the three homogenization step durations. In first image at 0 minutes we see that both depicted h-BN crystal domains are fully intact. This in marked contrast to the other two images. At 5 minutes the h-BN crystal domains have started to dissociate and damage is visible. At 10 minutes most h-BN crystal domains have fully dissociated and the remaining domains have significantly decreased in size. This further supports the theoretical discussion in relation to the discussion of FIG. 2 above.

FIG. 6C shows the corresponding SEM images for borazine introduced at 1×10⁻⁵ mbar for a time of 5 minutes for the three homogenization step durations. In first image at 0 minutes we see that two different size distributions of h-BN crystal domains a present, all of which are intact. Again this in marked contrast to the other two images. At 5 minutes the large h-BN crystal domains have started to dissociate and damage is visible, whereas the small h-BN crystal domains have disappeared. At 10 minutes most h-BN crystal domains have fully dissociated and the remaining domains have significantly decreased in size. This again further supports the theoretical discussion in relation to the discussion of FIG. 2 above.

FIG. 7 Illustrates the degree of further nucleation with precursor exposure duration during the domain expansion step. FIG. 7A summarises the experimental conditions for this comparative test. Again, the temperature is heated to 1200° C. and held at this temperature for 15 minutes. This is followed by a low borazine pressure growth step similar to the domain expansion step, step (d), discussed in relation to FIG. 1. Specifically, borazine is introduced during the growth step at 2.5×10⁻⁶ mbar for a variable duration. The three durations tested were 10 minutes, 15 minutes and 20 minutes. Again, after growth the sample was immediately quenched and imaged using SEM.

FIG. 7B shows the corresponding SEM images for the three conditions. Note, the scale bar applies to all three images. As can be seen, at 10 minutes no nucleation is apparent. However, by 15 minutes the onset of nucleation is observed. It is particular notable that this onset time of 15 minutes is approximately five times as long as for the high-pressure growth discussed above in relation to FIG. 5. By 20 minutes yet more nucleation events are observed together with significant domain expansion.

Taking the above-described comparative tests together it is possible see some of the trade-offs which enable the novel SSG process to grow high-quality h-BN with a small number of large-area h-BN crystal domains.

As one example, the extended nucleation time at the lower precursor pressure conditions of FIG. 7 compared with FIG. 5 allows for a time period, in this case up to around 15 minutes, when pre-existing h-BN crystal domains may be grown without risking significant further nucleation. This is simply not possible with conventional single growth step approaches. The presence of the homogenization step further assists with this as partial dissolution of h-BN nuclei ensures that small nuclei present immediately after the recrystallization/seeding step are likely to fully dissociate thus leading to a small number of more uniformly sized h-BN crystal domains going into the domain expansion step.

As set out in the background, an important motivation for developing the novel SSG process was to produce high-quality h-BN with a small number of large-area h-BN crystal domains. However, such high-quality h-BN would be of limited utility in the absence of a capability to transfer the h-BN to a desired device substrate without damaging or contaminating h-BN. It is furthermore desirable to avoid damage to the catalytic substrate such that it can be re-used for multiple growth cycles.

As recognised by the present inventor, prior approaches to enabling transfer had a number of deficiencies. One particular issue is the use of metal catalysts in the CVD growth purpose which strongly adhere to h-BN. Examples of strong adhesion metal catalysts include nickel, iron, cobalt, rhodium, palladium and ruthenium. Accordingly, it is desirable to use metal catalysts with a weak adhesion to h-BN such as platinum or copper.

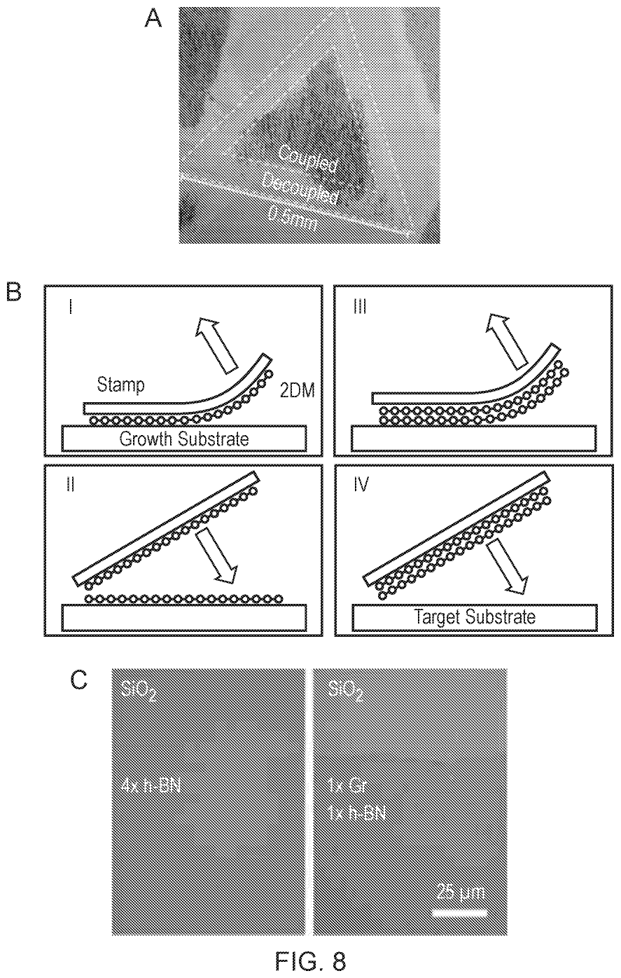

FIG. 8A illustrates weak adhesion to the substrate. The image shown is an SEM image of h-BN on platinum taken 5 hours after removing the sample from the CVD reactor. The weak adhesion can clearly be seen as the h-BN has begun to spontaneously decouple from the substrate. This is highlighted for clarity with the outer dotted lines marking the outer edge of the island and with an inner dotted line marking the limit between the coupled (darker) and decoupled (lighter) regions.

FIG. 8B illustrates the process flow diagram of the exfoliation based transfer for producing layer stacks (heterostructures). Prior to step I of the transfer process, a suitable carrier material such as PVA (polyvinyl alcohol) is drop cast onto the as-grown h-BN to form a “stamp”. Other suitable carrier materials include LOR (lift-off resist), PMMA (polymethyl methacrylate), PPC (polypropylene carbonate), PVB (polyvinyl butyral), CAB (cellulose acetate butyrate), PVP (polyvinylpyrrolidone), PC (polycarbonate) or any other suitable carrier material which has a higher adhesion to the h-BN than the h-BN has to the growth substrate.

If only a single layer of h-BN is desired the PVA stamp can simply be pressed against a device substrate, such as silicon dioxide, and the PVA substrate can be dissolved through the application of water without damaging or contaminating the h-BN. If other carrier materials are used, any suitable technique which does not damage the h-BN may be used to remove the carrier material. In some examples, this can include dissolving the carrier material using a suitable solvent, evaporating the carrier material or burning the carrier material off of the h-BN. It is further noted that this exfoliation process leaves the growth substrate undamaged and ready for re-use.

From one perspective there are two broad mechanisms by which carrier layers may be removed: dissolution and destruction. Examples of solvents which may be used to dissolve carrier materials include acetone, N-Methyl-2-pyrrolidone (NMP), dimethyl sulfoxide, hexane, benzene, diethyl ether, dimethylformamide, toluene, butyl acetate, ethyl acetate, ethanol, methanol, chloroform, dichloromethane, isopropanol and water. Examples of techniques which can be used to destroy carrier materials include plasma etching (using hydrogen, fluorine or oxygen), annealing (using oxygen or hydrogen) and acid/base treatment (using potassium hydroxide (KOH), acetic acid or nitric acid).

Alternatively, if a stack of layers is desired, the PVA stamp together with h-BN can be collectively used to pick up additional layers. This process is shown schematically in FIG. 8B steps II, III and IV. The joint stamp can be used in this manner since the adhesion between a layer of h-BN and a second layer of h-BN, graphene or other two-dimensional material on a weak-adhesion growth substrate is greater than the adhesion between the second h-BN layer, graphene layer or other two-dimensional material and its growth substrate.

FIG. 8C shows example layers stacks produced using this technique. On the left is an optical image of 4 layers of h-BN on a silicon dioxide substrate. On the right is an optical image of a layer of h-BN on top of a layer graphene which is itself on a silicon dioxide substrate.

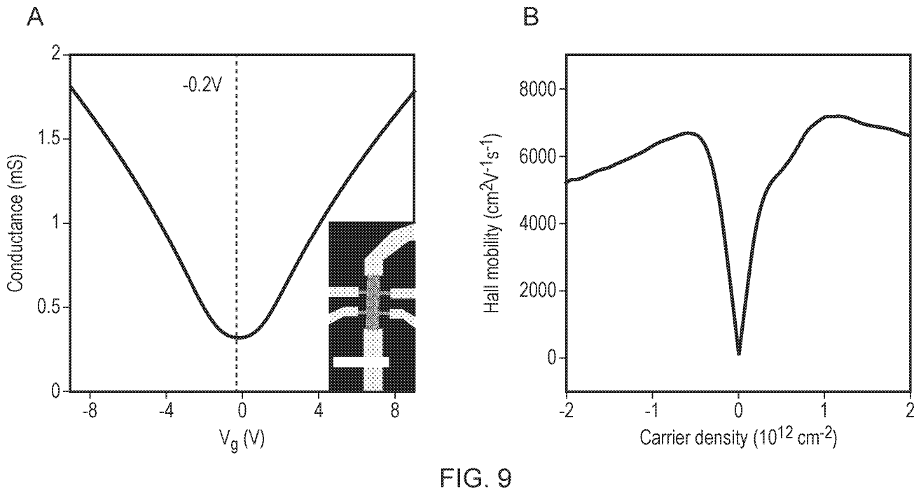

FIG. 9A shows the transfer characteristics obtained via a 4-terminal measurement of a representative h-BN/graphene field effect transistor (FET) device produced using the above-described techniques. The dotted lines show the Dirac point which is only shifted by −0.2V which is representative of the intrinsic proprieties of high-quality graphene. The inset to FIG. 9A is an optical image of the measured Hall bar fabricated using the disclosed techniques. The scale bar indicates 10 μm.

FIG. 9B shows a hall mobility measurement. The Hall mobility (μH), can be directly extracted from this measurement without assumptions as to the capacitance or curve fitting. A peak μH=7200 cm²V⁻¹s⁻¹ is measured at room temperature. Furthermore, a low intrinsic level of doping of n₀=4.8×10¹⁰ cm⁻² is measured, confirming a low doping level. This low doping is achieved without the need for any high temperature annealing to remove residuals post-transfer. The example device thus serves to demonstrate the high-quality devices which can be fabricated using disclosed techniques.

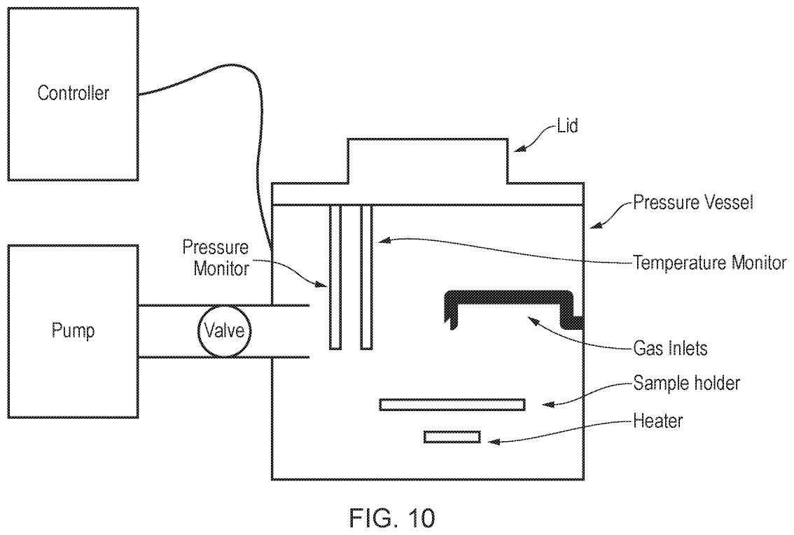

FIG. 10 is a diagram of an example CVD reactor which can be used in the manufacture of h-BN using the novel SSG technique. The sample is placed in or on a sample holder. The sample holder can either be an independent element or an integrated part of the heater itself. The reactor chamber is heated through the use of one or more heaters. Examples of suitable heaters include resistive heaters, laser heaters or electromagnetic heaters. The temperature is monitored during the process using one or more temperature measurement devices. Examples of suitable temperature measurement devices include thermocouples, pyrometers and resistive thermometers. The pressure is monitored during the process using one or more pressure measurement devices. Examples of suitable pressure measurement devices include capacitive pressure gauges, pirani pressure gauges and ionization pressure gauges. The precursor gases are fed into the chamber through one or more gas inlets. The pressure is regulated through control of one or more valves and pumps. Examples of suitable pumps include membrane pumps, rotary pumps and turbo molecular pumps. The reactor may be controlled through the use of an external control device which monitors the received sensor data and which controls the process parameters.

Therefore, as will be apparent from the above description, a novel technique for producing large areas (>0.5 mm compared to a few μm previously) of high-quality h-BN has been described which allows for straightforward transfer of the grown h-BN to a desired device substrate.

1. A method of producing hexagonal boron nitride by chemical vapour deposition on a substrate, the method comprising:
(a) a step of heating the substrate at a first temperature for a first time;
(b) a step of exposing the substrate to a precursor containing boron and a precursor containing nitrogen at a first partial pressure of the precursor(s) at a second temperature for a second time,
wherein either a single precursor is used as the precursor containing boron and as the precursor containing nitrogen or different precursors are used as the precursor containing boron and the precursor containing nitrogen;
(c) a step of heating the substrate at a third temperature for a third time without the precursor; and
(d) a step of exposing the substrate to the precursors at a fourth temperature at a second partial pressure of the precursor(s) for a fourth time.

2. A method according to claim 1 wherein the second partial pressure is lower than the first partial pressure.

3. A method according to claim 2 wherein the first partial pressure is between 1×10⁻⁶ mbar and 1×10⁻² mbar and the second partial pressure is between 1×10⁻⁷ mbar and 1×10⁻² mbar.

4. A method according to claim 3 wherein the first partial pressure is between 5×10⁻⁶ mbar and 1.5×10⁻⁵ mbar and the second partial pressure is between 1×10⁻⁶ mbar and 4×10⁻⁶ mbar.

5. A method according to claim 4 wherein the first partial pressure is between 9×10⁻⁶ mbar and 1.1×10⁻⁵ mbar and the second partial pressure is between 2×10⁻⁶ mbar and 3×10⁻⁶ mbar.

6. A method according to claim 1 wherein a single precursor is used as the precursor containing boron and the precursor containing nitrogen and wherein the precursor is one of borazine, ammonia borane and trichloroborazine.

7. A method according to claim 1 wherein the precursor containing boron is one triisopropyl borate, triphenylborane, boron trichloride, diborane and decaborane; and the precursor containing nitrogen is one of ammonia and nitrogen.

8. A method according to claim 1 wherein the substrate is platinum or a platinum alloy.

9. A method according to claim 8 wherein the substrate is platinum foil.

10. A method according to claim 8 wherein the substrate is formed of monocrystalline platinum.

11. A method according to claim 8 wherein the substrate is initially formed of polycrystalline platinum and step (b) causes recrystallization of the platinum substrate from polycrystalline to single crystal form.

12. A method according to claim 1 wherein the substrate is one of germanium, copper, silver, gold and iridium or the substrate is an alloy comprising one or more of germanium, copper, silver, gold and iridium.

13. A method according to claim 1 wherein the first temperature is between 900° C. and 1400° C. and/or the second temperature is between 900° C. and 1400° C. and/or the third temperature is between 900° C. and 1400° C. and/or the fourth temperature is between 900° C. and 1400° C.

14. A method according to claim 1 wherein the first temperature is between 1170° C. and 1250° C. and/or the second temperature is between 1170° C. and 1250° C. and/or the third temperature is between 1170° C. and 1250° C. and/or the fourth temperature is between 1170° C. and 1250° C.

15. A method according to claim 1 wherein the first temperature is between 1180° C. and 1220° C. and/or the second temperature is between 1180° C. and 1220° C. and/or the third temperature is between 1180° C. and 1250° C. and/or the fourth temperature is between 1180° C. and 1220° C.

16. A method according to claim 1 wherein the first, second, third and fourth temperatures are substantially the same.

17. A method according to claim 1 wherein the first time is at least 5 minutes.

18. A method according to claim 17 wherein the first time is at least 10 minutes.

19. A method according to claim 1 wherein the second time is between 1 minutes and 10 minutes.

20. A method according to claim 19 wherein the second time is between 2 minutes and 6 minutes.

21. A method according to claim 20 wherein the second time is between 3 minutes and 4 minutes.

22. A method according to claim 1 wherein the third time is between 1 minutes and 30 minutes.

23. A method according to claim 22 wherein the third time is between 2 minutes and 10 minutes.

24. A method according to 23 wherein the third time is between 4 minutes and 6 minutes.

25. A method according to claim 1 wherein the fourth time is between 5 minutes and 60 minutes.

26. A method according to claim 25 wherein the fourth time is between 5 minutes and 20 minutes.

27. A method according to claim 26 wherein the fourth time is between 8 minutes and 12 minutes.

28. A method of transfer of hexagonal boron nitride produced by the method of claim 1 from a first substrate to a second substrate, the method comprising:
(e) applying to the hexagonal boron nitride a carrier material, the carrier material having a higher adhesion to the hexagonal boron nitride than the adhesion of the hexagonal boron nitride to the first substrate, such that the hexagonal boron nitride adheres to the carrier material;
(f) removal of the carrier material having the hexagonal boron nitride adhered thereto from the first substrate;
(g) applying the carrier material having the hexagonal boron nitride adhered thereto to the second substrate; and
(h) removal of the carrier material.

29. A method according to claim 28 wherein the carrier material is one of LOR, PMMA, PPC, PVB, CAB, PVP, PC and PVA.

30. A method according to claim 28 wherein steps (e)-(h) are repeated a plurality of times to build up a plurality of layers of hexagonal boron nitride on the second substrate.

31. A method according to claim 28 wherein the second substrate is one of silicon, silicon dioxide, aluminium oxide, sapphire, germanium, gallium arsenide (GaAs), an alloy of silicon and germanium, and indium phosphide.

32. A chemical vapour deposition reactor configured to produce hexagonal boron nitride using the method of claim 1.

33. A controller configured to control a chemical vapour deposition reactor to produce hexagonal boron nitride using the method of claim 1.
